(19) United States
(12) Patent Application Publication
(10) Pub. No.: US 2005/0120958 A1
(43) Pub. Date: Jun. 9, 2005

(54) Reactor

(76) Inventor: Frank Lin, Hsin-Chu Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/707,345

(22) Filed: Dec. 7, 2003

(51) Int. Cl. C23C 16/00

(52) U.S. Cl. 118/723 R

(57) ABSTRACT

A reactor functions according to a control process. The reactor comprises a first valve and a second valve, a control unit for preventing the first valve and the second valve from being turned on simultaneously, and a process chamber. A first gas and a second gas are inducted into the process chamber through the first valve and second valve, which are respectively turned on. The control process sets the second valve and the first valve so that each of them is turned on one interval after the other is turned off, and a flow rate of either the first gas or the second gas is zero.

### BACKGROUND OF INVENTION

1. Field of the Invention

The present invention relates to a reactor, and more particularly, to a plasma enhanced chemical vapor deposition (PECVD) reactor for depositing a tetra-ethyl-ortho-silicate based silicon oxide (TEOS-based SiOₓ) layer and a silane-based silicon oxide (Si_{H}-based Si_{O}) layer in a process chamber.

2. Description of the Prior Art

Chemical vapor deposition (CVD) processes are extensively applied to display manufacturing processes, semi-conductor manufacturing processes, and other opto-electronics manufacturing processes. The CVD process involves changing gas reactants into solid products through chemical reactions in a chamber, and depositing a thin film on a substrate. Processes for CVD techniques have been developed for several decades and become one of the most important tools in thin film deposition commonly applied in the above-mentioned industry. Films of conductors, semiconductors, or dielectrics can all be produced by the CVD process. The PECVD process, being performed under 450° C. and producing films having good step coverage ability, low stress, and satisfactory electrical characteristics, has become anirreplaceable technique.

By utilizing the PECVD process, various dielectric thin films are produced. The silicon oxide films, formed by the PECVD process, are applied in different fields. A silicon oxide layer is not only used as a gate insulating (GI) layer or a capacitor dielectric layer, but is also used as an isolation layer or a planarization layer in liquid crystal display products. In addition, the silicon oxide layer is very frequently used in semiconductor products and opto-electronics products. The silicon oxide layer is classified into a silane-based silicon oxide layer or a TEOS-based silicon oxide layer, depending on reaction mechanism. The former uses silane (SiH₄) and nitrous oxide (N₂O) as reactant gases, and the latter uses tetra-ethyl-ortho-silicate (TEOS) and oxygen (O₂) or ozone (O₃) as reactant gases. Once silane and oxygen or ozone are mixed, combustion occurs immediately causing a safety problem. It thus becomes extremely important to process these two kinds of silicon oxide layers carefully.

Please refer to FIG.1. FIG. 1 is a schematic diagram of portions of a conventional PECVD reactor 10 for depositing a silane-based silicon oxide layer and a TEOS-based silicon oxide layer. As shown in FIG. 1, the conventional PECVD reactor 10 comprises a first gas valve 12 and a second gas valve 14. The first gas valve 12 is used for controlling a flow rate of silane, and the second gas valve 14 is used for controlling a flow rate of oxygen or ozone. The PECVD reactor 10 further comprises a plurality of process chambers. In FIG. 1, two process chambers 16, 18 are taken as an example for illustration. Silane is inducted into the process chamber 16 through the first gas valve 12 which is turned on, and oxygen or ozone is inducted into the process chamber 18 through the second gas valve 14 which is turned on. The first gas valve 12 and a first pipeline 22, for inducting silane into the process chamber 16, and the second gas valve 14 and a second pipeline 24, for inducting oxygen or ozone into the process chamber 18, are independent of each other. Furthermore, the process chamber 16 and the process chamber 18 are independent of each other by utilizing perfect vacuum technique. Therefore, gases will not leak out and mix.

The PECVD reactor 10 further comprises a third gas valve 26 for inducting TEOS into the process chamber 18. The first gas valve 12, the second gas valve 14, and the third gas valve 26 are all normally closed valves. That means, these three valves 12,14,16 are normally turned off. These three valves 12,14,16 are turned on to induct gases into the process chamber 16 and the process chamber 18 only when a control process of the PECVD reactor 10 asks a specific valve to be turned on, thereby starting a deposition process. In addition, each of the process chamber 16 and the process chamber 18 of the PECVD reactor 10 comprises at least one mass flow controller (MFC). These mass flow controllers control the flow rate of each gas inducted into each process chamber according to pre-set commands so that the flow rate of each gas is precisely controlled when processes are performed.

After each time or several times of deposition steps, a purge step or a plasma clean step may be performed to clean the process chamber 16 or the process chamber 18 under the instruction of pre-set commands. The purge step is performed by circulating a specific flow rate of nitrogen gas in some pipeline and in the process chamber for a predetermined time, and simultaneously carrying out residual gas in these pipelines and in the process chamber by a vacuum pump. The plasma clean step, being performed by combining physical and chemical mechanisms, is to remove silicon oxide deposition adhered on the wall of the process chamber. It is worth noting that the PECVD reactor 10, comprising two process chambers 16, 18, is taken as an example for illustration. In fact, the PECVD reactor 10 may comprise more than two process chambers. No matter how many process chambers the PECVD reactor 10 comprises, the gas valve and the pipeline for inducting silane into the process chamber must be independent of the gas valve and the pipeline for inducting oxygen of ozone into the process chamber, and each of the process chambers must be independent of the other process chambers to fulfill safety requirements.

Although silane and oxygen or ozone will not mix to cause safety problems with this hardware configuration, the equipment utilization is not efficient. The silane-based silicon oxide layer contains an eminent amount of hydrogen atoms that can be used as a hydrogen source to perform a hydrogenating process for repairing defects in the polysilicon thin film. However, it has bad step-coverage ability so that voids occur easily in the deposition process. The TEOS-based silicon oxide layer has good step-coverage ability in the deposition process, but cannot serve as a hydrogen source. Therefore, a subsequent hydrogenating process is needed for an additional hydrogen source, leading to increased cost of hydrogenating equipment and manufacturing time. Because each of the two kinds of silicon oxide films has its advantage and drawback, making one”s choice become a difficult work. Moreover, when each of the process chambers can only deposit one kind of silicon oxide film, some of the process chambers are frequently in an idle state, lowering productivity. In addition, the equipment cost is increased; the maintenance cost is also raised to result in extra personnel and material costs. As a result, the price of products is not competitive.

Therefore, it is very important to adjust the PECVD reactor to allow a single process chamber to deposit two different kinds of silicon oxide films. The efficiency of equipment utilization should be improved, the throughput should be increased, and the products with competitive price are fabricated.

### SUMMARY OF INVENTION

The present invention provides a PECVD reactor which can deposit a TEOS-based silicon oxide layer and a silane-based silicon oxide layer in a process chamber to solve the above-mentioned problems.

According to the claimed invention, a thin film deposition reactor comprises a first gas valve for controlling a flow rate of a first gas, a second gas valve for controlling a flow rate of a second gas, a control unit for controlling functions of the first gas valve and the second gas valve, and a process chamber connected to the first gas valve and the second gas valve for accommodating the first gas and the second gas and performing deposition processes. The first gas valve and the second gas valve are not turned on simultaneously such that the first gas or the second gas is inducted into the process chamber to perform the corresponding deposition process.

The present invention PECVD reactor utilizes a control unit in conjunction with a pre-set control process to control functions of the first gas valve and the second gas valve. The first gas valve and the second gas valve are thus prevented from being turned on simultaneously. By setting each of the mass flow controllers, silane and oxygen or ozone cannot flow into the process chamber simultaneously. In addition, thorough purge step and plasma clean steps are provided. Therefore, the present invention PECVD reactor can deposit the TEOS-based silicon oxide layer and the silane-based silicon oxide layer in the same process chamber. Under the circumstances, the process chamber is not left idle. Also, the extra personnel and material costs needed to maintain a separate piece of equipment are saved.

These and other objectives of the claimed invention will become obvious to those of ordinary skill in the art after having read the following detailed description of the preferred embodiment that is illustrated in the various figures and drawings.

### BRIEF DESCRIPTION OF DRAWINGS

FIG. 1 is a schematic diagram of portions of a conventional PECVD reactor for depositing a silane-based silicon oxide layer and a TEOS-based silicon oxide layer.

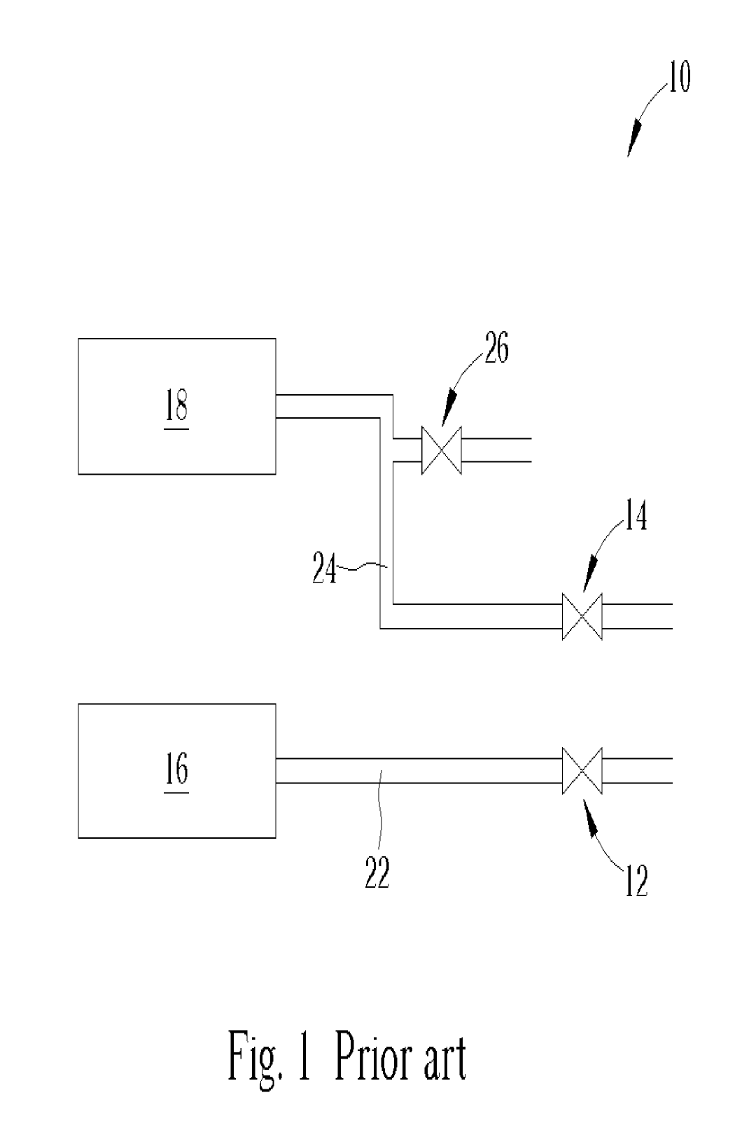

FIG. 2 is a schematic diagram of portions of a present invention PECVD reactor for depositing a silane-based silicon oxide layer and a TEOS-based silicon oxide layer.

### DETAILED DESCRIPTION

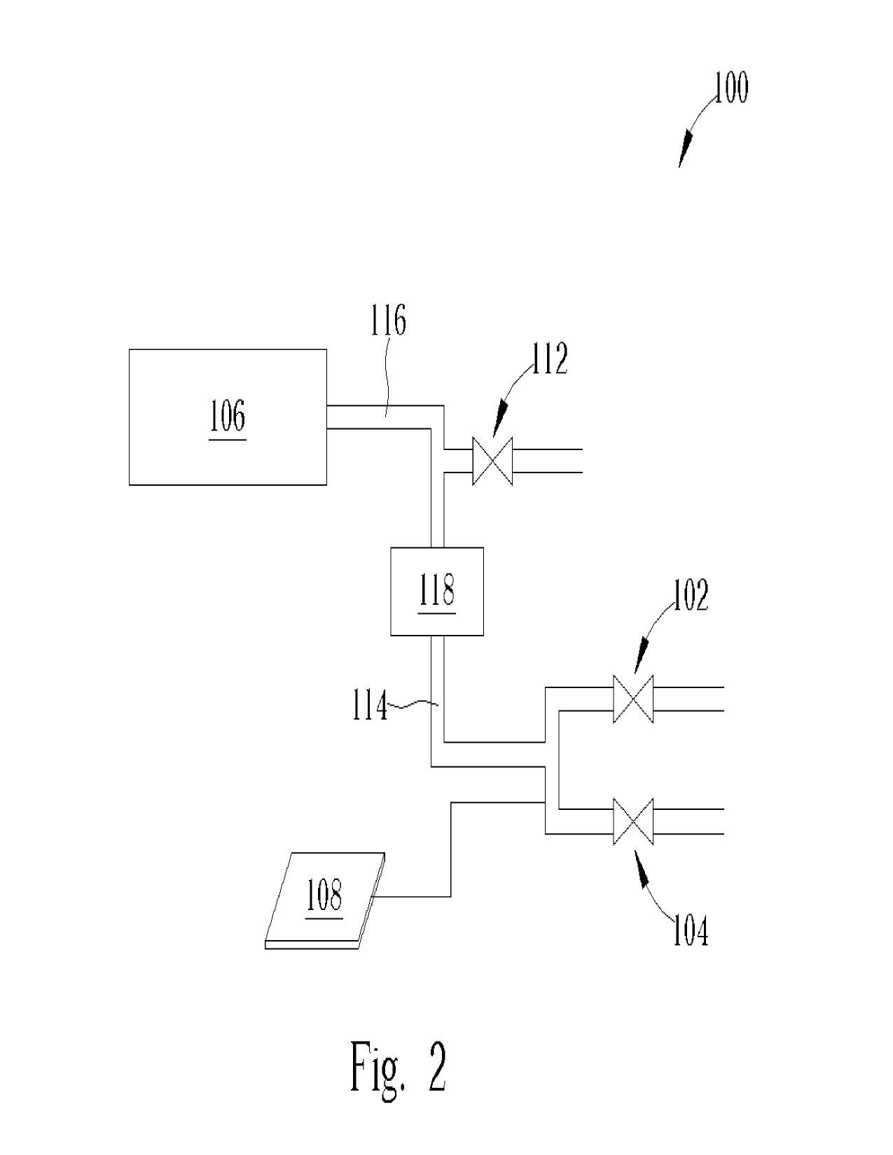

Please refer to FIG. 2. FIG. 2 is a schematic diagram of portions of a present invention PECVD reactor 100 for depositing a silane-based silicon oxide layer and a TEOS-based silicon oxide layer. As shown in FIG. 2, the present invention PECVD reactor 100 comprises a first gas valve 102 and a second gas valve 104. The first gas valve 102 is used for controlling a flow rate of silane, and the second gas valve 104 is used for controlling a flow rate of oxygen or ozone. Since silane is used for providing hydrogen, it is also called a hydrogen-based (H-based) gas. Similarly, since oxygen or ozone is used for providing oxygen, they are also called oxygen-based (O-based) gases.

PECVD reactor 100 further comprises at least one process chamber. In FIG. 2, one process chamber 106 is taken as an example for illustration. Silane is inducted into the process chamber 106 through the first gas valve 102 which is turned on, and oxygen or ozone is inducted into the process chamber 106 through the second gas valve 104 which is turned on. The PECVD reactor 100 further comprises a control unit 108 for accepting commands of a control process to prevent the first gas valve 102 and the second gas valve 104 from being turned on simultaneously. The control unit 108, being a logic circuit, functions as a logic gate. Therefore, the control unit 108 will control the first gas valve 102 and the second gas valve 104 according to the commands of the control process after the control process pre-set that the first gas valve 102 and the second gas valve 104 cannot be turned on simultaneously.

The PECVD reactor 100 further comprises a third gas valve 112 for inducting TEOS into the process chamber 106. The first gas valve 102, the second gas valve 104, and the third gas valve 112 are all normally closed valves. That means, these three valves are normally turned off. These three valves are turned on to induct gases into the process chamber 106 only when the control process of the PECVD reactor 100 asks a specific valve to be turned on, then starting a deposition process. In addition, the process chamber 106 of the PECVD reactor 100 comprises at least one mass flow controller. Each mass flow controller is used for controlling a flow rate of each gas inducted into the process chamber 106 according to the pre-set commands of the control process so that the flow rate of each gas is precisely controlled when processes are performed.

In fact, the PECVD reactor 100 functions according to the control process. The control process not only sets that the first gas valve 102 and the second gas valve 104 cannot be turned on simultaneously, but also sets the first gas valve 102 and the second gas valve 104 so that each of them is turned on one interval after the other is turned off. Moreover, the control process sets that either of the flow rates of silane and oxygen or ozone is zero. The interval is set according to practical requirements, for example: 30 seconds.

When the control process sets that the PECVD reactor 100 needs to deposit the silane-based silicon oxide layer, the first gas valve 102 is turned on and the second gas valve 104 and the third gas valve 112 are turned off. Silane is therefore inducted into the process chamber 106 to perform deposition process together with another reactant gas. At the same time, one of the mass flow controllers will prevent any oxygen or ozone from flowing into the process chamber 106 since the control process sets the flow rate of oxygen or ozone to zero. When the control process sets that the PECVD reactor 100 needs to deposit the TEOS-based silicon oxide layer, the first gas valve 102 is turned off and the second gas valve 104 and the third gas valve 112 are turned on. Oxygen or ozone and TEOS are therefore inducted into the process chamber 106 to perform deposition process. At the same time, another mass flow controller will prevent any silane from flowing into the process chamber 106 since the control process sets the flow rate of silane to zero. Consequently, silane and oxygen or ozone will not mix and burn even though the silane-based silicon oxide layer and the TEOS-based silicon oxide layer are deposited in the same process chamber 106. As a result, the PECVD reactor 100 will operate smoothly under an adequate safety mechanism.

In order to ensure that the PECVD reactor 100 operates safely, the control process sets a purge step and the purge step is performed after each silicon oxide film deposition. By circulating a specific flow rate of nitrogen gas for a predetermined time, residual gas in pipelines 114, 116 between both of the first and second gas valves 102, 104 and the process chamber 106 and residual gas in the process chamber 106 are simultaneously carried out by a vacuum pump. The PECVD reactor 100 further comprises a remote plasma cleaning system (RPCS) 118 installed between the first gas valve 102, the second gas valve 104, and the process chamber 106. A plasma clean step is thus performed after each purge step according to the setting of the control process. By inputting NF₃ gas and combining physical and chemical reaction mechanisms, residual gas and byproducts in pipeline 116 connected to the process chamber 106 and in the process chamber 106 are cleaned out. The remote plasma cleaning system 118 transforms the cleaning gases into plasma before they enter the process chamber 106, and plasma is thereafter input into the process chamber 106. Therefore, plasma will selectively remove the substances on the wall of the process chamber 106 without damaging the metal and ceramic in the process chamber 106. As a result, the quality of formed films and the yield of devices are obviously improved.

It is worth noting that the PECVD reactor 100, comprising one process chamber 106, is taken as an example for illustration. In fact, the PECVD reactor 100 may comprise a plurality of process chambers. No matter how many process chambers the PECVD reactor 100 comprises, the software and the hardware are designed according to the principle of the present invention such that the PECVD reactor 100 can fulfill the safety requirements. In addition, the first gas valve 102 and the second gas valve 104 are not limited in controlling the flowing of silane and oxygen or ozone, respectively. The first gas valve 102 may be used for controlling the flowing of oxygen or ozone, and the second gas valve 104 may be used for controlling the flowing of silane. Under the circumstances, the design and settings for the software and the hardware need to be revised correspondingly.

The present invention PECVD reactor utilizes a control unit in conjunction with a pre-set control process to control the first gas valve and the second gas valve so as to prevent the first gas valve and the second gas valve from being turned on simultaneously. Therefore, silane and oxygen or ozone cannot flow into the process chamber simultaneously. In addition, thorough purge step and plasma clean steps are provided. As a result, safety problems are not caused. In summary, the present invention PECVD reactor can deposit the TEOS-based silicon oxide layer and the silane-based silicon oxide layer in the same process chamber. When applying the present invention PECVD reactor to a practical production line, products having high throughput and low cost are fabricated.

Compared with the prior art PECVD reactor, which deposits the TEOS-based silicon oxide layer and the silane-based silicon oxide layer in different process chambers, the present invention PECVD reactor utilizes a control unit in conjunction with a pre-set control process to control the first gas valve and the second gas valve. The first gas valve and the second gas valve are thus prevented from being turned on simultaneously. By setting each of the mass flow controllers, silane and oxygen or ozone cannot flow into the process chamber simultaneously. Furthermore, thorough purge step and plasma clean steps are provided. Therefore, the present invention PECVD reactor can deposit the TEOS-based silicon oxide layer and the silane-based silicon oxide layer in the same process chamber. Under the circumstances, the process chamber is not idled to lower productivity. The equipment cost and maintenance cost are not raised to result in extra personnel and material costs. As a result, the price of products will be very competitive.

Those skilled in the art will readily observe that numerous modifications and alterations of the device may be made while retaining the teaching of the invention. Accordingly, the above disclosure should be construed as limited only by the metes and bounds of the appended claims.

1. A reactor comprising:
a first gas valve for controlling a flow rate of a first gas;
a second gas valve for controlling a flow rate of a second gas;
a control unit for controlling the first gas valve and the second gas valve; and
a process chamber connected to the first gas valve and the second gas valve for accommodating the first gas and the second gas and performing deposition processes;
wherein the first gas valve and the second gas valve are not turned on simultaneously such that the first gas and the second gas are inducted into the process chamber in separate intervals to perform their corresponding deposition processes.

2. The reactor of claim 1, wherein the reactor is a plasma enhanced chemical vapor deposition (PECVD) reactor.

3. The reactor of claim 1, wherein both the first gas valve and the second gas valve are normally closed valves.

4. The reactor of claim 1, wherein the first gas is a hydrogen-based (H-based) gas.

5. The reactor of claim 1, wherein the second gas is an oxygen-based (O-based) gas.

6. The reactor of claim 1, wherein the control unit is a logic circuit.

7. The reactor of claim 1, wherein the process chamber comprises at least one mass flow controller (MFC) for accepting commands of a pre-set control process to control the flow rates of the first gas and the second gas.

8. The reactor of claim 1, wherein each of the first gas valve and the second gas valve is turned on one interval after the other is turned off.

9. The reactor of claim 1, wherein residual gas in pipelines between both of the first and second gas valves and the process chamber and residual gas in the process chamber are cleaned out by a purge step.

10. The reactor of claim 1, further comprising a remote plasma cleaning system (RPCS) installed between the first gas valve, the second gas valve, and the process chamber, and the RPCS is used for cleaning residual gas and byproducts.

11. The reactor of claim 1, further comprising a third gas valve for inducting a tetra-ethyl-ortho-silicate (TEOS) into the process chamber.

12. A reactor for depositing a tetra-ethyl-ortho-silicate based silicon oxide layer and a silane-based silicon oxide layer in a process chamber comprising:
a first gas valve for controlling a flow rate of a hydrogen-based (H-based) gas;
a second gas valve for controlling a flow rate of an oxygen-based (O-based) gas;
a third gas valve for controlling a flow rate of tetra-ethyl-ortho-silicate (TEOS);
a control unit for controlling functions of the first gas valve and the second gas valve; and
the process chamber connected to the first gas valve and the second gas valve for accommodating the hydrogen-based gas and the oxygen-based gas and performing deposition processes;
wherein the first gas valve and the second gas valve are not turned on simultaneously such that the hydrogen-based gas or the oxygen-based gas is inducted into the process chamber to perform the corresponding deposition process.

13. The reactor of claim 12, wherein the reactor is a plasma enhanced chemical vapor deposition (PECVD) reactor.

14. The reactor of claim 12, wherein the first gas valve, the second gas valve and the third gas valve are normally closed valves.

15. The reactor of claim 12, wherein the hydrogen-based gas is silane (SiH₄), and the oxygen-based gas comprises oxygen (O₂) or ozone (O₃).

16. The reactor of claim 12, wherein the control unit is a logic circuit.

17. The reactor of claim 12, wherein the process chamber comprises at least one mass flow controller (MFC) for accepting commands of a control process to control the flow rates of the hydrogen-based gas and the oxygen-based gas.

18. The reactor of claim 12, wherein each of the first gas valve and the second gas valve is turned on one interval after the other is turned off.

19. The reactor of claim 12, wherein residual gas in pipelines between both of the first and second gas valves and the process chamber and residual gas in the process chamber are cleaned out by a purge step.

20. The reactor of claim 12, further comprising a remote plasma cleaning system (RPCS) installed between the first gas valve, the second gas valve, and the process chamber, and the RPCS is used for cleaning residual gas and byproducts.
